(19) United States
(12) Patent Application Publication
(10) Pub. No.: US 2008/0171435 A1
(43) Pub. Date: Jul. 17, 2008

(54) Vacuum Processing Apparatus, Method for Manufacturing Semiconductor Device, and System For Manufacturing Semiconductor Device

(75) Inventors: Takahiro Fujii, Tokyo (JP); Yukihito Tashiro, Tokyo (JP); Seiji Itani, Tokyo (JP); Motozo Kurita, Tokyo (JP)

Correspondence Address: BUCHANAN, INGERSOLL & ROONEY PC, POST OFFICE BOX 1404, ALEXANDRIA, VA, 22313-1404, US

(73) Assignee: Canon ANELVA Corporation, Kawasaki-shi (JP)

(21) Appl. No.: 11/989,319

(22) PCT Filed: Jul. 25, 2006
(86) PCT No.: PCT/JP2006/314619

§ 371 Date: Feb. 13, 2008

(30) Foreign Application Priority Data
Jul. 25, 2005 (JP) 2005-214550

(51) Int. Cl. H01L 21/44; C23C 16/00

(52) U.S. Cl. 438/680; 118/719

(57) ABSTRACT

A vacuum processing apparatus including at least three transfer chambers that have transfer robot arms for transferring a substrate, one or more processing chambers connected to each of the transfer chambers; one or more substrate mounts disposed in the interior thereof; a single common vacuum chamber in which the transfer robot arms of the at least three transfer chambers are disposed in positions that allow the arms to reach the substrate mount, and which is used for handing off the substrate by the transfer robot arms between at least two transfer chambers and at least one substrate mount; and load-lock chambers connected to at least one transfer chamber.

### TECHNICAL FIELD

The present invention relates to a vacuum processing apparatus that allows for complicated substrate processes via a simple and compact chamber layout, a method for manufacturing a semiconductor device that uses the vacuum processing apparatus, and a system for manufacturing a semiconductor device.

### BACKGROUND ART

From the viewpoint of forming multiple layers of device structures and improving or otherwise increasing throughput, vacuum processing apparatuses used for treating semiconductor wafers or other substrates to manufacture semiconductor devices are increasingly being provided with a plurality of processing chambers for carrying out various processes in a vacuum using a single apparatus in an integrated manner. Examples of processes for semiconductor wafers include film formation (sputtering, CVD, and the like), oxidation, dispersion, etching, annealing, and other preprocess and post-processes. Examples of embodiments of such vacuum processing apparatuses include inline and cluster apparatuses. With such vacuum processing apparatuses, a plurality of substrates is ordinarily transferred into a cassette via load-lock chambers; and each of the plurality of substrates is sequentially loaded according to a prescribed procedure into the transfer area, the handoff area, and the processing area, and treated using single wafer processing. Examples of prior art that disclose a conventional vacuum processing apparatus provided with two or more transfer chambers include the following four Patent Documents 1 to 4.

The apparatus described in Patent Document 1 (Japanese Laid-open Patent Publication No. 4-199709) is a continuous processing apparatus provided with transfer chambers (31 to 36) connected to one or more processing chambers. With this continuous processing apparatus, a processing object is transferred into the transfer chambers (31 to 36), and one or more processes are successively carried out in the processing chambers. Two or more transfer chambers are provided, and buffer chambers (41 to 45) connected to the transfer chambers are disposed between two transfer chambers.

The apparatus disclosed in Patent Document 2 (Japanese Laid-open Patent Publication No. 2000-150618) is a vacuum processing system for treating substrates and other processing objects and is provided with a sputtering chamber, a CVD chamber, and a plurality of other processing units. With this vacuum processing system, two transfer chambers (16, 30) having a transfer arm that transfer processing objects are provided, and at least one processing unit is connected via a gate valve to each of the two transfer chambers (16, 30). A vacuumable intermediate path chamber (38) having an internally disposed stage (40) is interposed between the two transfer chambers. The configuration of two transfer chambers and an intermediate path chamber therebetween avoids complicating the transfer pathway related to the transfer of processing objects, thereby improving throughput.

The apparatus described in Patent Document 3 (Japanese Laid-open Patent Publication No. 7-288238) is a multi-chamber processing apparatus for separately subjecting a plurality of substrates loaded into a single apparatus to different processes in a plurality of processing chambers. With this multi-chamber processing apparatus, a first transfer module and a second transfer module that are connected in series via a handoff module, and the transfer pathway of the substrates as processing objects is not structured as a returnable pathway.

The processing system described in Patent Document 4 (Japanese Laid-open Patent Publication No. 2003-59999) is provided with three transfer chambers, i.e., a single common transfer chamber (36) and two separate transfer chambers (72), in a single vacuum processing system. A plurality of processing apparatuses (34A to 34D) are connected to the single common transfer chamber, and a single preprocessing apparatus (110), for example, is connected to each of the two separate transfer chambers. The two separate transfer chambers (72) are connected to the common transfer chamber (36) via a separate second buffer chamber (74) disposed between the separate transfer chambers.

A strong demand exists for a vacuum processing apparatus that is designed for manufacturing semiconductor devices and is capable of handling complicated substrate processes needed to manufacture the multilayered structures of semiconductor devices likely to be created in the future, by using processing chambers and other elements provided with simple and compact layouts.

In particular, the vacuum processing apparatus disclosed in Patent Documents 1 and 2 does not satisfy the requirements described above. In other words, the vacuum processing apparatus disclosed in Patent Documents 1 and 2 has a configuration that cannot be kept compact when an attempt is made to handle complicated substrate processes.

With the processing system described in Patent Document 4, three transfer chambers are provided, but the system does not have a common single vacuum chamber for substrate handoff among the three transfer chambers. For this reason, a compact chamber layout that can handle complicated substrate processes cannot be implemented.

As described above, an apparatus configuration that adequately solves the problem of providing a simple and compact chamber layout has not yet been proposed for a conventional vacuum processing apparatus capable of handling complicated substrate processes.

Patent Document 1: Japanese Laid-open Patent Publication No. 4-199709)

Patent Document 2: Japanese Laid-open Patent Publication No. 2000-150618)

Patent Document 3: Japanese Laid-open Patent Publication No. 7-288238)

Patent Document 4: Japanese Laid-open Patent Publication No. 2003-59999)

### DISCLOSURE OF THE INVENTION

### Problems the Invention is to Solve

The problem the present invention is to solve relates to a vacuum processing apparatus that can handle complicated substrate processes, and an object of the present invention is to provide an apparatus configuration in which a simpler and more compact chamber layout can be achieved in comparison with conventional vacuum processing apparatuses.

In other words, the present invention was contrived in view of the foregoing, and an object thereof is to provide a vacuum processing apparatus that can handle complicated substrate processes by using a simpler and more compact chamber layout in comparison with conventional apparatuses.

Another object of the present invention is to provide a method for manufacturing a semiconductor device through the use of the vacuum processing apparatus described above, and a system for manufacturing a semiconductor device through the use of the vacuum processing apparatus described above.

The vacuum processing apparatus, method for manufacturing a semiconductor device, and system for manufacturing a semiconductor device according to the present invention are constituted in the following manner in order to achieve the above-stated objects.

The vacuum processing apparatus of the present invention comprises at least three transfer chambers each of which is provided in the interior thereof with a transfer robot arm for transferring a substrate; processing chambers at least one of which is connected to each of the transfer chambers, and inside which the substrate is treated; a single common vacuum chamber inside which one or more substrate mounts are disposed, in which the transfer robot arm of each of the at least three transfer chambers is disposed so as to be capable of reaching the substrate mounts, and which is used by the transfer robot arm to hand off the substrate among at least two of the transfer chambers and at least one of the substrate mounts; and load-lock chambers connected to at least one of the transfer chambers.

With the vacuum processing apparatus described above, complicated substrate processes can be handled by a simple and compact chamber layout composed of three transfer chambers and a common vacuum chamber used for substrate handoff and disposed in an intermediate position of the three transfer chambers.

Preferably, in the configuration described above, the transfer robot arms of the transfer chambers are capable of moving the substrate to the substrate mounts inside the common vacuum chamber.

Preferably, in the configuration described above, four or more of the transfer chambers are provided.

Preferably, in the configuration described above, a single handoff vacuum chamber is disposed between at least one set of two adjacent transfer chambers among the at least three transfer chambers.

Preferably, in the configuration described above, the load-lock chambers are separately provided to each of the two transfer chambers.

Preferably, in the configuration described above, the common vacuum chamber is provided with the one or more rotatable substrate mounts and an alignment sensor, whereby a substrate alignment function is provided.

Preferably, in the configuration described above, the common vacuum chamber is provided with one or both of a heater stage for heating and a cooling stage for cooling, whereby a substrate heating/cooling function is provided.

Preferably, in the configuration described above, the common vacuum chamber is provided with a monitor apparatus for monitoring a surface state of the substrate, whereby a substrate monitor function is provided.

Preferably, in the configuration described above, the common vacuum chamber is provided with a cassette that is capable of accommodating a plurality of substrates, a mechanism for elevating/lowering the cassette, and a rotation mechanism for rotating the cassette, whereby a substrate stocker function is provided.

Preferably, in the configuration described above, the transfer chambers, the common vacuum chamber, and the handoff vacuum chamber are partitioned by a gate valve.

Preferably, in the configuration described above, the plurality of processing chambers connected to the same transfer chamber are processing chambers that belong to the same category and are classified by the processing pressure and the content and extent of contamination brought about by the processing.

Preferably, in the configuration described above, the common vacuum chamber is a chamber for performing at least one operation selected from aligning the substrate, heating the substrate, cooling the substrate, monitoring a surface state of the substrate, and stocking the substrate.

The method for manufacturing a semiconductor device according to the present invention is a method comprising preparing a vacuum processing apparatus described above, and subjecting a substrate to at least three processes using the vacuum processing apparatus.

Furthermore, the method for manufacturing a semiconductor device according to the present invention is a method for manufacturing a semiconductor device that includes a wafer process, the wafer process having an oxidation step that is carried out in a first processing chamber among at least three processing chambers that are provided to a vacuum processing apparatus described above; a CVD step that is carried out in a second processing chamber provided to the vacuum processing apparatus; and an electrode formation step that is carried out in a third processing chamber provided to the vacuum processing apparatus.

Preferably, the method for manufacturing a semiconductor device described above is one in which the wafer process includes a resist processing step, an exposure step, a development step, and an etching step that are carried out in an apparatus other than the vacuum processing apparatus after the oxidation step, the CVD step, and the electrode formation step have been carried out in the vacuum processing apparatus.

The system for manufacturing a semiconductor device according to the present invention comprises the vacuum processing apparatus described above, a resist coater, a stepper, a resist developer, and an etcher to carry out a wafer process. The wafer process includes at least three substrate processing steps, and at least three substrate processing steps are carried out in the vacuum processing apparatus.

Furthermore, the system for manufacturing a semiconductor device according to the present invention comprises the vacuum processing apparatus described above, a resist coater, a stepper, a resist developer, and an etcher to carry out a wafer process. The wafer process includes an oxidation step, a CVD step, and an electrode formation step; and the vacuum processing apparatus has a first processing chamber for carrying out the oxidation step, a second processing chamber for carrying out the CVD step, and a third processing chamber for carrying out the electrode formation step.

Preferably, in the configuration described above, the oxidation step, the CVD step, and the electrode formation step are carried out in the vacuum processing apparatus, whereupon the resist coater performs a resist processing step, the stepper performs an exposure step, the resist developer performs a development step, and the etcher performs an etching step.

### EFFECT OF THE INVENTION

In accordance with the present invention, in the vacuum processing apparatus, a basic configuration of a chamber layout is achieved based on at least three transfer chambers connecting one or more processing chambers, and a single common vacuum chamber for substrate handoff that is in an intermediate position between the three transfer chambers and which is connected to the three transfer chambers. For this reason, the possibility of sharing a substrate transfer pathway or sharing a substrate process can be expanded and complicated substrate processes can be handled while maintaining a simpler and more compact chamber layout by using the apparatus configuration itself, or a combination with other substrate handoff vacuum chambers.

The degree of freedom of selecting the transfer pathway in the vacuum processing apparatus can be increased, the degree of freedom of combining substrate processes can be increased and complicated substrate processes can be handled by using a basic configuration composed of the three transfer chambers and a single common vacuum chamber between the transfer chambers. Complicated substrate processes can thereby be efficiently implemented with high productivity. The flexibility of the chamber layout of various processing chambers, transfer chambers, and the like can be increased by using such a basic configuration.

In accordance with a system for manufacturing a semiconductor device that uses such a vacuum processing apparatus, a semiconductor device can be efficiently fabricated at low cost.

### BEST MODE FOR CARRYING OUT THE INVENTION

The preferred embodiments of the present invention are described below with reference to the attached drawings.

### Embodiment 1

The first embodiment of the vacuum processing apparatus of the present invention will be described with reference to FIG. 1. FIG. 1 is a plan view that schematically shows the vacuum processing apparatus of the first embodiment of the present invention.

In FIG. 1, a vacuum processing apparatus 1 is provided with three transfer chambers 11, 12, and 13 in a relatively proximate positional relationship. The transfer chambers 11, 12, and 13 are provided with transfer robot arms 11a, 12a, and 13a, respectively, in the interior thereof, preferably in the center position. The transfer robot arms 11a to 13a are mechanisms that transfer a substrate (for the sake of convenience, hereinafter referred to as “wafer”) as a processing object. The transfer chambers 11 to 13 are each independently provided with a vacuum evacuation apparatus and a transfer robot arm controller, which are not shown. The transfer robot arms 11a to 13a are capable of rotating about a center shaft section 14, and the arm sections 15 thereof are retractable. The arm sections 15 can move in the vertical direction. In this example, the transfer robot arms 11a to 13a are provided with a substantially semicircular substrate handoff section on the two sides the arms. In the example of the transfer robot arms 11a to 13a that are shown, a substrate mount 16 is provided to the two sides.

The shape and structure of each of the transfer robot arms is not limited to the above, and any shape of the arm or mechanism can be used, including a retracting mechanism and a vertical movement mechanism, as long as a substrate can be transferred from a common vacuum chamber to a processing chamber or vice versa.

The three transfer chambers 11 to 13 are disposed so as to be located in the apical positions of a triangle in the manner shown in FIG. 1. Each of the three transfer chambers 11 to 13 is fabricated as a single isolated transfer chamber apparatus.

A single common vacuum chamber 21 is provided to a substantially intermediate location of the three transfer chambers 11 to 13. The common vacuum chamber 21 has an internally disposed single substrate mount 21a and is provided with a vacuum evacuation apparatus, which is not shown in the drawings. The pressure of the common vacuum chamber 21 is reduced to a required level by the vacuum evacuation apparatus. Gate valves 22, 23, and 24 are disposed in a boundary wall section between the single common vacuum chamber 21 and the three transfer chambers 11 to 13. The gate valves 22 to 24 can be opened to establish communication between the interiors of adjacent chambers with each other, and substrates can thereby be moved between the chambers. Each of the gate valves 22 to 24 can be closed off to isolate the adjacent chambers from each other. The gate valves 22 to 24 are operated by a controller (not shown) with suitable timing in accordance with the substrate process.

The common vacuum chamber 21 has, as a basic configuration, a single substrate mount 21a, and is not provided with a special substrate transfer mechanism such as the transfer robot arm described above. Therefore, as viewed from the three transfer chambers 11 to 13, the common vacuum chamber 21 functions as a substrate handoff vacuum chamber for moving substrates as processing objects to the transfer robot arm of another transfer chamber. From another viewpoint, the common vacuum chamber 21 is used as a single transfer pathway that moves the substrate.

Since the substrate is handed off via the common vacuum chamber 21 between the three transfer chambers 11 to 13, the position of the substrate mount 21a of the common vacuum chamber 21 is set so as to be reachable by the transfer robot arms 11a to 13a of the three transfer chambers 11 to 13. Therefore, the transfer robot arms 11a to 13a of the three transfer chambers 11 to 13 can place the substrate on the substrate mount 21a of the common vacuum chamber 21 and remove the substrate placed on the substrate mount 21a, assuming that the gate valves 22, 23, and 24 are open.

The chamber configuration composed of the three transfer chambers 11 to 13 described above and a single common vacuum chamber 21 positioned in the center of the three transfer chambers is a basic configuration of the vacuum processing apparatus 10. The common vacuum chamber 21 is shared as a substrate handoff chamber.

The common vacuum chamber 21 may also be configured to be capable of being used as a processing chamber for subjecting a substrate to prescribed processes as required in the design of the vacuum processing apparatus 1. In this case, heating means, cooling means, and the like are provided, whereby by heating, cooling, annealing, alignment, and other processes are carried out. Specific examples of these processes are described below.

As an example, a single processing chamber is connected to each of the three transfer chambers 11 to 13 described above via a gate valve 41. A processing chamber 51 is connected to the transfer chamber 11, a processing chamber 61 is connected to the transfer chamber 12, and a processing chamber 71 is connected to the transfer chamber 13. The processing chambers connected to the three transfer chambers 11 to 13 preferably belong to a category differentiated based on the vacuum level (pressure level) and the vacuum quality (cleanness, i.e., the content and extent of contamination) of each of the transfer chambers.

The details of the process carried out in the processing chambers 51, 61 and 71 may also be arbitrarily set in accordance with the object of the treated substrate. In the drawings, the circular portions depicted inside the transfer chambers show substrate mounts.

Load-lock chambers 81 and 82 are connected to the two transfer chambers 11 and 12 positioned to the left and right on the underside in FIG. 1 via gate valves 81a and 82a.

With the vacuum processing apparatus 1 having the chamber layout described above, the degree of freedom of selecting the transfer pathway for moving the substrate is increased and the degree of freedom of combining various processes to which substrates are subjected can be increased, based on the fact that a basic configuration composed of the three transfer chambers 11 to 13 and a single common vacuum chamber 21 in the center thereof is provided.

Next, the functions of the vacuum processing apparatus 1 that can be provided by the common vacuum chamber 21 or the processes that can be performed by the chamber will be described in detail.

The common vacuum chamber 21 is preferably provided with the gate valves 22, 23, and 24 between the three transfer chambers 11 to 13, has an independent vacuum evacuation system, and is provided with at least one function selected from, e.g., the first to fourth functions described below.

The first function is an aligner function. In a common vacuum chamber 21 having an aligner function, an aligner is provided having a rotatable wafer stage (corresponding to the substrate mount 21a) and a sensor required for alignment. The substrate, i.e., the wafer loaded into the common vacuum chamber 21 and mounted on the wafer stage is arranged by rotating the wafer stage, whereby a wafer notch or orientation flat is detected and the center position of the wafer is computed based on the sensor information. The wafer is rotated and the center position information is presented to the handoff transfer robot in order to set the wafer notch (with consideration given to the center position) relative to the three transfer chambers 11 to 13 in an optimal orientation. The wafer is aligned by this series of operations.

The second function is a heating/cooling function. In a common vacuum chamber 21 having a heating/cooling function, the configuration is provided with one or both of a heater stage for heating and a cooling stage for cooling inside the common vacuum chamber, and has at least a heater or a cooler that heats and/or cools the wafer. The treatment chambers 51, 61, and 71 connected to the three transfer chambers 11 to 13 have one or both of a heating mechanism and a cooling mechanism, and the temperature can be brought in advance to the treatment temperature in the next transfer chamber by using the heating/cooling mechanism of the common vacuum chamber 21 when the wafer is to be transferred to another transfer chamber via the three transfer chambers 11 to 13. The heating time or the cooling time can thereby be reduced prior to treatment in the transfer chambers 51, 61, and 71, and overall treatment time can be reduced.

The third function is a monitor function. In a common vacuum chamber 21 having a monitor function, a monitor apparatus for monitoring the surface state of the wafer is provided. The wafer is sent into the common vacuum chamber 21 and placed on the wafer stage (substrate mount 21a) when a desired treatment is completed in the transfer chambers 51, 61, and 71 that are connected to the transfer chambers 11 to 13. The state of the wafer surface is monitored by the monitor apparatus mounted in the common vacuum chamber 21. The results of the monitoring are used to determine the normality of the treatment in the transfer chamber. The monitoring result can also be used to correct the treatment recipe in the treatment chamber that carried out the treatment. The monitoring result can also be used to correct the treatment recipe in a treatment chamber that is subsequent thereto. The monitor apparatus may, for example, be a non-contact optical film thickness meter such as a spectroscopic ellipsometer that is used when film thickness is to be monitored, or a RHEED (Reflection High-Energy Electron Diffraction) that is used when crystallinity is to be monitored.

The fourth function is a wafer stocker function. In a common vacuum chamber 21 having a wafer stocker function, a multi-shelved cassette that can accommodate a plurality of wafers is provided, as are a mechanism for elevating the cassette and a rotation mechanism for orienting the cassette toward the transfer chambers 11 to 13.

Until now, seasoning aimed at preparing the condition of a treatment module immediately after the start of wafer production entailed the use of a dummy wafer, the loading of the dummy wafer from a cassette 86, and the sending of the dummy wafer to a treatment chamber by a transfer chamber via a load lock. The dummy wafer was recovered using the reverse procedure.

However, the dummy wafer is stocked in a vacuum when the wafer stocker function is performed inside the common vacuum chamber 21 in the manner described above. Therefore, the dummy wafer can be transferred into a treatment chamber by way of the transfer chambers 11 to 13 when all of the treatment modules require seasoning. According to this procedure, the transfer time can be reduced, seasoning can be started immediately, and, as a result, the time until production starts can be reduced. The dummy wafer recovery work time can furthermore be reduced in a similar manner.

The following application examples can be considered when a wafer stocker function is performed inside the common vacuum chamber 21.

A target cleaning process is required when the treatment module is a PVD module. Generally, a shutter mechanism is disposed inside the treatment module when DC sputtering in used, and the shutter is closed to perform target cleaning. However, a phenomenon occurs in which plasma migrates around to the rear side of the shutter because there is a gap between the shutter and the stage when RF sputtering is used, and there are cases in which the shutter cannot be used. In view of this situation, the wafer may be sent into the treatment module, placed on the wafer stage, and used in place of a shutter to carry out target cleaning. There are also cases in which the wafer used in place of the shutter and the mechanism for transferring the wafer may be held inside the treatment module in order to reduce the transfer time.

In the above case, when the common vacuum chamber 21 is used to stock a wafer, the wafer is transferred from the common vacuum chamber 21 to the treatment chambers connected to the required transfer chambers (11, 12, and 13) at the required time during target cleaning. The wafer can be returned to the original common vacuum chamber 21 when target cleaning is completed. For this reason, the treatment chambers considerably reduce the time that elapses until cleaning starts, and a complicated transfer mechanism does not need to be kept inside the treatment modules.

A further description of the transfer chambers 11, 12, and 13 and the treatment chambers 51, 61, and 71 of the vacuum treatment apparatus 1 will be provided below.

A preferred example that underscores the significance of providing the vacuum treatment apparatus 1 of the first embodiment with three transfer chambers 11 to 13 is an example in which a tungsten plug (W-Plug) is formed in a contact hole. The wafer treatment procedure in the process of forming a W-Plug in a contact hole entails moving the wafer in sequence through the treatment chambers 51, 71, and 61.

The treatment chamber 51 that performs the first treatment preferably has a chemical substrate-preprocessing function. The object of the treatment chamber 51 is to remove a natural oxide film from the bottom part of the contact hole. Examples of the treatment gas used include NH₃ and H₂. The oxide film is dissociated using plasma at a pressure of several pascals. The natural film layer of the surface of the substrate, and the contact hole (diffusion layer) in particular, is removed using the reducing properties of hydrogen (H).

The treatment chamber 71 that performs the next treatment preferably has a sputtering function. The object of the treatment chamber 71 is to form a Ti/TiN film inside the contact hole. The Ti/TiN film is formed in order to assure a seed layer of the subsequent bracket W and to assure a barrier function of the side surfaces of the contact hole. The background pressure prior to treatment must be 1×10E⁻⁵ Pa or less, the gases used for the actual treatment are Ar and N₂, and the film is formed at a pressure of 0.1 to several tens of pascals.

The treatment chamber 61 that performs the final treatment preferably has a CVD function. The object of the treatment chamber 61 is to form a plug inside the contact hole. The gases used are WF₆, N₂, H₂, and the like, and the film is formed at pressure of several pascals.

The transfer chambers 11 to 13 preferably have the following functions in relation to the treatment chambers, which have been designed so as to have the functions described above.

The transfer chamber 11 preferably has a background pressure of 1×10E⁻⁵ Pa or less. On the other hand, the pressure is higher than the pressure of the treatment chamber 51 when the gate valve 41 is opened. This setting is used to prevent residual gas from diffusing from the treatment chamber 51 to the transfer chamber 11 when the gate valve 41 is opened, and to prevent re-oxidation when the oxygen partial pressure inside the transfer chamber 11 is reduced.

The pressure of the transfer chamber 13 is preferably the same as the background pressure of the treatment chamber 71. This is to prevent impure gas from being taken into the sputtering film.

The pressure of the transfer chamber 12 is preferably higher than the pressure of the treatment chamber 61. This setting is used to prevent residual gas from diffusing from the treatment chamber 61 to the transfer chamber 12 when the gate valve 41 is opened.

Since the degree of vacuum of the transfer chambers 11, 12, and 13 is considerably different as described above, the transfer chambers are preferably connected via the common vacuum chamber 21 rather than being directly connected to each other.

The transfer chambers 11, 12, and 13 that differ in terms of the degree of contamination (cleanness) of the vacuum are preferably connected via the common vacuum chamber 21.

In accordance with the vacuum treatment apparatus 1 of the first embodiment, since access to at least the three transfer chambers 11 to 13 having mutually different functions in the manner described above can be shared and the substrate can be handed off, the function of the shared portion of the plurality of treatment chambers is concentrated in the common vacuum chamber 21, the treatment chambers and the treatment modules are structurally simplified, and the surface area occupied by the apparatus overall can be reduced. There is also an advantage in that a shortcut is also made possible in which a substrate is transferred directly from the transfer chamber 11 to the transfer chamber 12 and an improvement in throughput can be expected, depending on the application.

In accordance with the vacuum treatment apparatus 1 of the first embodiment, three transfer chambers 11 to 13 are provided, whereby treatment zones can be apportioned for each transfer chamber with consideration given to the contamination. For example, the transfer chamber 11 is a chemical treatment zone, the transfer chamber 13 is a sputtering treatment zone, and the transfer chamber 12 is a CVD treatment zone. A substrate is transferred from the load-lock chamber 81 to the transfer chamber 11 and treated in the treatment chamber 51 connected thereto; the substrate is subsequently transferred to the transfer chamber 13 and treated in the treatment chamber 71 connected thereto; the substrate is then transferred to the transfer chamber 12 and treated in the treatment chamber 61 connected thereto; and the substrate is discharged from the unload-lock chamber 82. Such a substrate transfer pathway is one-way and the substrate does not return in the reverse direction. Therefore, there is an advantage in that the substrate is not affected by contamination from the treatment chambers connected to the transfer chambers.

### Embodiment 2

Next, the second embodiment of the vacuum treatment apparatus of the present invention will be described with reference to FIG. 2. FIG. 2 is a plan view that schematically shows the vacuum treatment apparatus of the second embodiment. In FIG. 2, the same reference numerals are used for essentially the same elements as those described in FIG. 1, and a redundant description is omitted.

In the same manner as the vacuum treatment apparatus 1 of the first embodiment, the vacuum treatment apparatus 10 shown in FIG. 2 is provided with three transfer chambers 11, 12, and 13. The transfer chambers 11, 12, and 13 are provided with transfer robot arms 11a, 12a, and 13a in the interior thereof. A single common vacuum chamber 21 is disposed in a substantially intermediate location of the three transfer chambers 11 to 13. The three transfer chambers 11 to 13, the transfer robot arms 11a, 12a, and 13a, the common vacuum chamber 21, and the structure related to these elements are the same as described in the first embodiment.

With the vacuum treatment apparatus 10 shown in FIG. 2, separate vacuum chambers 31 and 32 are adjacently disposed to the left and right of the common vacuum chamber 21. The vacuum chamber 31 is disposed between the transfer chamber 11 and the transfer chamber 13. The vacuum chamber 32 is disposed between the transfer chamber 12 and the transfer chamber 13. In a basic configuration, the vacuum chambers 31 and 32 are each provided with a single substrate mount 31a and 32b in the same manner as the common vacuum chamber 21, and are not provided with a special substrate transfer mechanism. The vacuum chambers 31 and 32 function as substrate handoff chambers and are used as a transfer pathway. The vacuum chambers 31 and 32 are hereinafter referred to as handoff vacuum chambers 31 and 32. Gate valves 33 and 34 are disposed between the vacuum chamber 31 and the transfer chambers 11 and 13. Gate valves 35 and 36 are disposed between the handoff vacuum chamber 32 and the transfer chambers 12 and 13. The gate valves 33 to 36 are opened and closed with a suitable timing by a controller (not shown). A substrate is handed off by the transfer robot arms 11a and 13a of the transfer chambers 11 and 13 via the handoff vacuum chamber 31. The substrate is handed off by the transfer robot arms 12a and 13a of the transfer chambers 12 and 13 via the handoff vacuum chamber 32.

In the above description, the handoff vacuum chambers 31 and 32 may also be configured so as to be capable of being used as treatment chambers for subjecting a substrate to a prescribed treatment process. In this case, heating means, cooling means, or the like are provided to thereby heat, cool, anneal, align, or carry out other processes.

A gate valve 37 is disposed between the transfer chambers 11 and 12. The gate valve 37 is opened and closed with a suitable timing by a controller (not shown). The substrate is handed off by the transfer robot arms 11a and 12a between the transfer chambers 11 and 12 via the gate valve 37.

Also possible is a configuration in which a handoff vacuum chamber having the same function as the handoff vacuum chambers 31 and 32 described above is disposed between the transfer chamber 11 and the transfer chamber 12 to hand off the substrate between the transfer chambers 11 and 12 via the handoff vacuum chamber and to perform a prescribed process.

With the vacuum processing chamber 10 of the second embodiment, one or more processing chambers are preferably connected to the three transfer chambers 11 to 13 via the gate valve 41. As an example, two processing chambers 51 and 52 are connected to the transfer chamber 11, two processing chambers 61 and 62 are connected to the transfer chamber 12, and five processing chambers 71, 72, 73, 74, and 75 are connected to the transfer chamber 13.

The processing chambers connected to the transfer chambers 11 to 13 are preferably processing chambers that belong to the same category and are classified by the vacuum level (pressure level) and the vacuum quality (cleanness, i.e., the content and extent of contamination) of each of the transfer chambers. The details of the process carried out in the processing chambers 51, 52, 61, 62, and 71 to 75 are arbitrarily set in accordance with the purpose of using the treated substrate. The circular portions depicted inside the transfer chambers show substrate mounts.

Load-lock chambers 81 and 82 are connected to the two transfer chambers 11 and 12 positioned to the left and right on the underside in FIG. 2 via gate valves 81a and 82a. A loading/unloading apparatus 85, and three substrate accommodation units 86 provided with a substrate loading/unloading robot 84 are disposed outside of the load-lock chambers 81 and 82 via a gate valve 83.

With the vacuum processing apparatus 10 of the second embodiment as well, the degree of freedom of selecting the transfer pathway for moving the substrate is increased and the degree of freedom of combining various processes to which substrates are subjected can be increased, based on the fact that a basic configuration composed of the three transfer chambers 11 to 13 and a common vacuum chamber 21 is set up in the center of the vacuum processing apparatus in the same manner as the first embodiment.

Next, FIG. 3 shows an example of the substrate transfer pathway as a top view in the transfer chambers 11 to 13, the common vacuum chamber 21, the handoff vacuum chambers 31 and 32, and other components of the vacuum processing apparatus 10. In this transfer pathway, the gate valves in the transfer pathway are opened and closed with a suitable timing.

The substrate loaded into the transfer chamber 11 through the load-lock chamber 81 is held by the transfer robot arm 11a of the transfer chamber 11 and is kept inside the transfer chamber 11 (pathway R1). When the substrate is kept inside the transfer chamber 11, the substrate is subjected to a required process using the processing chambers 51 and 52 connected to the transfer chamber 11, for example.

Next, the substrate is transferred by the transfer robot arm 11a from the transfer chamber 11 to the handoff vacuum chamber 31 and mounted on a substrate mount 31a (pathway R2). The transfer robot arm 13a of the transfer chamber 13 then removes the substrate that is placed on the handoff vacuum chamber 31 and transfers the substrate into the transfer chamber 13 (pathway R3). The substrate is held by the transfer robot arm 13a in the transfer chamber 13 and is kept in the transfer chamber. When the substrate is kept inside the transfer chamber 13, the substrate is subjected to a required process using one or a plurality of the processing chambers 71 to 75 connected to the transfer chamber 13.

The transfer robot arm 13a of the transfer chamber 13 then mounts the substrate on the substrate mount 21a of the common vacuum chamber 21 (pathway R4). Next, the transfer robot arm 11a of the transfer chamber 11 transfers the substrate inside the common vacuum chamber 21 to the transfer chamber 11 (pathway R5). The substrate held by the transfer robot arm 11a inside the transfer chamber 11 is handed off to the transfer robot arm 12a of the transfer chamber 12 via the gate valve 37 (pathway R6). The substrate is held by the transfer robot arm 12a in the transfer chamber 12 and is kept inside the transfer chamber 12. When the substrate is kept inside the transfer chamber 12, the substrate is subjected to a required process using the processing chambers 61 and 62 connected to the transfer chamber 12.

The transfers described above are essentially the same thereafter, i.e., the substrate is sequentially transferred via the pathway R7 between the transfer chamber 12 and the common vacuum chamber 21, the pathway R8 between the common vacuum chamber 21 and the transfer chamber 13, the pathway R9 between the transfer chamber 13 and the handoff vacuum chamber 32, the pathway R10 between the handoff vacuum chamber 32 and the transfer chamber 12, and the pathway R11 between the transfer chamber 12 and the load-lock chamber 82.

In the substrate transfer pathways R1 to R11 described above, a plurality of processing chambers connected to the transfer chambers can be suitably selected and a substrate can be subjected to a required process when the substrate is in any of the transfer chambers 11, 12, and 13. In this manner, in accordance with vacuum processing apparatus 10, the configuration composed of the three transfer chambers 11 to 13 and the common vacuum chamber 21 is used as a basic configuration, whereby the degree of freedom of selecting the transfer pathway for moving the substrate is increased and the degree of freedom of combining various processes to which substrates are subjected can be increased.

Next, a typical operational example of the substrate process will be described with reference to FIG. 4 from the viewpoint of a substrate process that is carried out using the vacuum processing apparatus 10.

FIG. 4 shows a diagrammatic conceptual view of only the layout of the chambers of the vacuum processing apparatus 10, and shows the specific movement pathway (R101 to R113) of the substrate for the substrate process. In FIG. 4, the same reference numerals are used for the same chambers as those described in FIG. 2. The transfer robot arms 11a to 13a disposed inside the transfer chambers 11 to 13 are omitted from the diagram.

In the process shown in FIG. 4, the substrate is first set inside the load-lock chamber 81 (pathway R101). The substrate inside the load-lock chamber 81 is moved by the transfer robot arm 11a through the interior of the transfer chamber 11 and is loaded into the processing chamber 51 (pathway R102). Radical etching (a preprocessing) is carried out in the processing chamber 51, and the surface of the substrate is cleaned.

Next, the substrate inside the processing chamber 51 is moved by the transfer robot arm 11a of the transfer chamber 11 through the interior of the transfer chamber 11 and transferred to the substrate mount of the handoff vacuum chamber 31 (pathway R103). The substrate on the substrate mount is thereafter transferred by the transfer robot arm 13a of the transfer chamber 13 into the transfer chamber 13 and is loaded into the processing chamber 71 (pathway R104). At this point, the substrate is heat treated in the handoff vacuum chamber 31, and the surface of the substrate is cleaned. PVD (Physical Vapor Deposition) is carried out in the processing chamber 71, and a Ti film is formed by sputtering on the surface of the substrate.

Next, the substrate inside the processing chamber 71 is unloaded by the transfer robot arm 13a of the transfer chamber 13 and transferred to the substrate mount inside the common vacuum chamber 21 (pathway R105). The transfer robot arm 11a of the transfer chamber 11 thereafter loads the substrate into the processing chamber 52 (pathway R106). A pre process by heating or plasma is carried out in the processing chamber 52.

The substrate is passed through the common vacuum chamber 21 rather than the handoff vacuum chamber 31 when the substrate is moved from the processing chamber 71 to the processing chamber 52, and the substrate wait time can be eliminated and throughput improved by dividing the movement pathway of the substrate.

Next, the substrate inside the processing chamber 52 is transferred by the transfer robot arm 11a of the transfer chamber 11 to the substrate mount inside the common vacuum chamber 21 (pathway R107). The substrate is thereafter loaded by the transfer robot arm 12a of the transfer chamber 12 into the processing chamber 61 (pathway R108). A CVD (Chemical Vapor Deposition) process is carried out in the processing chamber 61, and a TiN film is formed on the surface of the substrate.

Next, the substrate inside the processing chamber 61 is transferred by the transfer robot arm 12a of the transfer chamber 12 to the substrate mount inside the handoff vacuum chamber 32 (pathway R109). The substrate is thereafter loaded by the transfer robot arm 13a of the transfer chamber 13 into the processing chamber 73 (pathway R110). A PVD process is carried out in the processing chamber 73, and an Al film is formed in a heated state on the surface of the substrate.

Next, the substrate inside the processing chamber 73 is loaded by the transfer robot arm 13a of the transfer chamber 13 into the processing chamber 74 (pathway R111). A PVD processing process is carried out in the processing chamber 74, and a TiN antireflection film is formed on the surface of the substrate.

Lastly, the substrate inside the processing chamber 74 is transferred by the transfer robot arm 13a of the transfer chamber 13 to the substrate mount inside the common vacuum chamber 21 (pathway R112). The substrate is thereafter loaded by the transfer robot arm 12a of the transfer chamber 12 into the load-lock chamber 82 (pathway R113).

In the description above, passage from one position to another is merely an operation performed in the movement of the substrate from the processing chamber 71 to the processing chamber 52, the movement of the substrate from the processing chamber 52 to the processing chamber 61, and the movement of the substrate from the processing chamber 74 to the load-lock chamber 82. Therefore, the movement pathways are configured to be shared so that the substrate passes through the common vacuum chamber 21 in synchronism with other processing time periods. The waiting time can thereby be reduced and throughput can be improved. The configuration of the apparatus can be made compact and streamlined substrate movement can be achieved.

As described above, in accordance with the vacuum processing apparatus 10 having the chamber layout configuration shown in FIG. 2, various processes can be combined with a high degree of freedom on the basis of the substrate transfer or movement pathway shown in FIG. 3 or 4. Various processes can be combined by dispensing with a process, returning to a previous process, or otherwise freely designing the method of transferring the substrate as the processing object in the vacuum processing apparatus 10 of the present embodiment. The degree of freedom in combining processes can thus be increased. Therefore, substrate process can be made more efficient, productivity can be increased, and the flexibility of the layout of the various processing chambers, transfer chambers, and other components can be increased.

Additionally, the details of the processes of the processing chambers connected to each of the transfer chambers (11 to 13) can be classified into separate categories based on the vacuum level (pressure level) and quality (content and extent of the contamination). Cross-contamination by microparticles, gas, and other factors caused by the mutual relationship between the different processes can thereby be reduced.

Following is a description of operational examples 1 to 5 of other substrate processes that can be performed using the vacuum processing apparatus 10 of the second embodiment described above.

### Operational Example 1

Operational example 1 is a substrate process related to “contact filling.” FIG. 5 shows a specific substrate movement pathway (R201 to R213) that corresponds to the substrate process of operational example 1, and is the same diagram as FIG. 4. In FIG. 5, the same reference numerals are used for the same chambers as those described in FIG. 2. The transfer robot arms 11a to 13a disposed inside the transfer chambers 11 to 13 are omitted from the diagram.

In the process shown in FIG. 5, the substrate is first set inside the load-lock chamber 81 (pathway R201). The substrate inside the load-lock chamber 81 is moved by the transfer robot arm 11a of the transfer chamber 11 through the interior of the transfer chamber 11 and is loaded into the processing chamber 51 (pathway R202). A chemical pre process is carried out in the processing chamber 51.

Next, the substrate inside the processing chamber 51 is moved by the transfer robot arm 11a of the transfer chamber 11 through the interior of the transfer chamber 11 to the processing chamber 52 (pathway R203). A preprocess by heating or plasma is carried out in the processing chamber 52.

Next, the substrate inside the processing chamber 52 is transferred by the transfer robot arm 11a of the transfer chamber 11 through the interior of the transfer chamber 11, and transferred to the substrate mount of the handoff vacuum chamber 31 (pathway R204). The substrate on the substrate mount is thereafter transferred by the transfer robot arm 13a of the transfer chamber 13 into the transfer chamber 13 and is loaded into the processing chamber 71 (pathway R205). At this point, the substrate is preheated in the handoff vacuum chamber 31. The processing time in the processing chamber 71 is thereby reduced. PVD (Physical Vapor Deposition) is carried out in the processing chamber 71, and a Ti or Co film is formed by sputtering on the surface of the substrate.

Next, the substrate inside the processing chamber 71 is unloaded by the transfer robot arm 13a of the transfer chamber 13, and transferred to the substrate mount inside the common vacuum chamber 21 (pathway R206). The transfer robot arm 12a of the transfer chamber 12 thereafter loads the substrate into the processing chamber 61 (pathway R207). An ALD (Atomic Layer Deposition) process is carried out by CVD in the processing chamber 61. A preheating process is carried out in the common vacuum chamber 21. As a result, the processing time in the processing chamber 61 can be reduced.

Next, the substrate inside the processing chamber 61 is transferred by the transfer robot arm 12a of the transfer chamber 12 to the substrate mount inside the handoff vacuum chamber 32 (pathway R208). The substrate is thereafter loaded by the transfer robot arm 13a of the transfer chamber 13 into the processing chamber 72 (pathway R209). A PVD process is carried out in the processing chamber 72, and an Al seed layer is formed in a heated state on the surface of the substrate. A cooling process is carried out in the handoff vacuum chamber 32. The processing time in the processing chamber 72 can thereby be reduced.

The movement pathway of the substrate is divided and the processes are differentiated between the common vacuum chamber 21 and the handoff vacuum chamber 32, whereby the substrate processing times are synchronized, the substrate wait time is eliminated, throughput is improved, and flexible processes can be handled.

Next, the substrate inside the processing chamber 72 is loaded by the transfer robot arm 13a of the transfer chamber 13 into the processing chamber 73 (pathway R210). A PVD process that embeds Al in a hole is carried out in the processing chamber 73.

Next, the substrate inside the processing chamber 73 is transferred by the transfer robot arm 13a of the transfer chamber 13 to the substrate mount inside the common vacuum chamber 21 (pathway R211). The substrate is thereafter loaded by the transfer robot arm 12a of the transfer chamber 12 into the processing chamber 62 (pathway R212). A CVD process is carried out in the processing chamber 62, and a TiN antireflection film is formed on the surface of the substrate. A preheating process is carried out in the common vacuum chamber 21. As a result, the processing time in the processing chamber 62 can be reduced.

Lastly, the substrate inside the processing chamber 62 is loaded by the transfer robot arm 12a of the transfer chamber 12 into the load-lock chamber 82 (pathway R213).

In the substrate process of operational example 1 described above, with the movement of the substrate from the processing chamber 71 to the processing chamber 61 and the movement of the substrate from the processing chamber 73 to the processing chamber 62, the heat process in the common vacuum chamber 21 can be shared, the configuration of the apparatus can be made compact, and streamlined substrate movement can be achieved.

### Operational Example 2

Operational example 2 is a substrate process related to “contact barrier formation.” FIG. 6 shows a specific substrate movement pathway (R301 to R308) that corresponds to the substrate process of operational example 2, and is the same diagram as FIG. 4. In FIG. 6, the same reference numerals are used for the same chambers as those described in FIG. 2. The transfer robot arms 11a to 13a disposed inside the transfer chambers 11 to 13 are omitted from the diagram.

In the process shown in FIG. 6, the substrate is first set inside the load-lock chamber 81 (pathway R301). The substrate inside the load-lock chamber 81 is moved by the transfer robot arm 11a through the interior of the transfer chamber 11 and loaded into the processing chamber 51 (pathway R302). A chemical process is carried out in the processing chamber 51.

Next, the substrate inside the processing chamber 51 is moved by the transfer robot arm 11a of the transfer chamber 11 through the interior of the transfer chamber 11 to the processing chamber 52 (pathway R303). A heating or plasma process is carried out in the processing chamber 52.

Next, the substrate inside the processing chamber 52 is transferred by the transfer robot arm 11a of the transfer chamber 11 through the interior of the transfer chamber 11, and transferred to the substrate mount of the handoff vacuum chamber 31 (pathway R304). The substrate on the substrate mount is thereafter transferred by the transfer robot arm 13a of the transfer chamber 13 into the transfer chamber 13 and is loaded into the processing chamber 71 (pathway R305). At this point, the substrate is preheated in the handoff vacuum chamber 31. The processing time in the processing chamber 71 is thereby reduced. PVD (Physical Vapor Deposition) is carried out in the processing chamber 71, and a Co or Ti film is formed by sputtering on the surface of the substrate.

Next, the substrate inside the processing chamber 71 is unloaded by the transfer robot arm 13a of the transfer chamber 13 and transferred to the substrate mount inside the common vacuum chamber 32 (pathway R306). The transfer robot arm 12a of the transfer chamber 12 thereafter loads the substrate into the processing chamber 61 (pathway R307). A TiN film formation process is carried out by ALD (Atomic Layer Deposition) in the processing chamber 61. A preheating process is carried out in the common vacuum chamber 32. As a result, the processing time in the processing chamber 61 can be reduced.

Lastly, the substrate inside the processing chamber 61 is loaded by the transfer robot arm 12a of the transfer chamber 12 into the load-lock chamber 82 (pathway R308).

In the substrate process of operational example 2 described above, the heat process in the handoff vacuum chambers 31 and 32 is also carried out in the common vacuum chamber 21, and the heating process can also be carried out in the common vacuum chamber 21. Processing times are thereby synchronized with other processing times, the substrate wait time can be reduced, and throughput can be improved.

### Operational Example 3

Operational example 3 is a substrate process related to “via formation (Al filling).” FIG. 7 shows a specific substrate movement pathway (R401 to R410, R417, and R418) that corresponds to the substrate process of operational example 3, and is the same diagram as FIG. 4. In FIG. 7, the same reference numerals are used for the same chambers as those described in FIG. 2. The transfer robot arms 11a to 13a disposed inside the transfer chambers 11 to 13 are omitted from the diagram.

In the process shown in FIG. 7, the substrate is first set inside the load-lock chamber 81 (pathway R401). The substrate inside the load-lock chamber 81 is moved by the transfer robot arm 11a through the interior of the transfer chamber 11 and is loaded into the processing chamber 51 (pathway R402). A chemical process is carried out in the processing chamber 51, and the surface of the substrate is pre-etched.

Next, the substrate inside the processing chamber 51 is moved by the transfer robot arm 11a of the transfer chamber 11 through the interior of the transfer chamber 11 and transferred to the substrate mount of the handoff vacuum chamber 31 (pathway R403). The substrate on the substrate mount is thereafter transferred by the transfer robot arm 13a of the transfer chamber 13 into the transfer chamber 13 and is loaded into the processing chamber 71 (pathway R404). At this point, the substrate is heated in the handoff vacuum chamber 31, and the surface of the substrate is cleaned. PVD (Physical Vapor Deposition) is carried out in the processing chamber 71, and a Ti film is formed by sputtering on the surface of the substrate.

Next, the substrate inside the processing chamber 71 is unloaded by the transfer robot arm 13a of the transfer chamber 13 and loaded into the neighboring processing chamber 72 (pathway R405). A PVD process is carried out in the processing chamber 72, and a TiN film is formed on the surface of the substrate. The substrate inside the processing chamber 72 is thereafter unloaded by the transfer robot arm 13a of the transfer chamber 13 and loaded into the neighboring processing chamber 73 (pathway R406). A PVD process is carried out in the processing chamber 73, and a Ti film is formed on the surface of the substrate.

Next, the substrate inside the processing chamber 73 is transferred by the transfer robot arm 13a of the transfer chamber 13 to the substrate mount inside the handoff vacuum chamber 32 (pathway R407). The substrate is thereafter loaded by the transfer robot arm 12a of the transfer chamber 12 into the processing chamber 61 (pathway R408). A PVD process is carried out in the processing chamber 61, and an Al seed layer is formed on the surface of the substrate. A cooling process is carried out in the handoff vacuum chamber 32. The processing time in the processing chamber 61 can thereby be reduced.

In the above description, it is also possible to transfer the substrate from the processing chamber 73 to the processing chamber 61 via the pathways R417 and R418 in place of the pathways R407 and R408, using the common vacuum chamber 21. A cooling process is carried out in the common vacuum chamber 21.

Next, the substrate inside the processing chamber 61 is unloaded by the transfer robot arm 12a of the transfer chamber 12 and then loaded into the neighboring processing chamber 62 (pathway R409). A PVD process that embeds Al in a hole is carried out in the processing chamber 62.

Lastly, the substrate inside the processing chamber 62 is loaded by the transfer robot arm 12a of the transfer chamber 12 into the load-lock chamber 82 (pathway R410).

In the substrate process of operational example 3 described above, the cooling process in the handoff vacuum chamber 32 requires time to be carried out. Therefore, substrate movement is also carried out in the common vacuum chamber 21 and the substrate can also be cooled in the common vacuum chamber 21. Processing times are thereby synchronized with other processing times, the substrate wait time in substrate movement can be reduced, and throughput can be improved.

### Operational Example 4

Operational example 4 is a substrate process related to “salicide processing.” FIG. 8 shows a specific substrate movement pathway (R501 to R509) that corresponds to the substrate process of operational example 4, and is the same diagram as FIG. 4. In FIG. 8, the same reference numerals are used for the same chambers as those described in FIG. 2. The transfer robot arms 11a to 13a disposed inside the transfer chambers 11 to 13 are omitted from the diagram.

In the process shown in FIG. 8, the substrate is first set inside the load-lock chamber 81 (pathway R501). The substrate inside the load-lock chamber 81 is moved by the transfer robot arm 11a of the transfer chamber 11 through the interior of the transfer chamber 11 and loaded into the processing chamber 51 (pathway R502). A chemical process is carried out in the processing chamber 51.

Next, the substrate inside the processing chamber 51 is moved by the transfer robot arm 11a of the transfer chamber 11 through the interior of the transfer chamber 11 into the processing chamber 52 (pathway R503). A heating or plasma process is carried out in the processing chamber 52.

The substrate inside the processing chamber 52 is transferred by the transfer robot arm 11a of the transfer chamber 11 through the transfer chamber 11 to the substrate mount of the handoff vacuum chamber 31 (pathway R504). The substrate on the substrate mount is thereafter transferred by the transfer robot arm 13a of the transfer chamber 13 into the transfer chamber 13 and loaded into the processing chamber 71 (pathway R505). At this point, the substrate is preheated in the handoff vacuum chamber 31. The processing time in the processing chamber 71 can thereby be reduced. PVD is carried out in the processing chamber 71, and a film composed of Co, Ni, Ti, or Y, Yb, Er, or another rare earth metal is formed by sputtering on the surface of the substrate.

Next, the substrate inside the processing chamber 71 is unloaded by the transfer robot arm 13a of the transfer chamber 13 and loaded into the neighboring processing chamber 72 (pathway R506). PVD is carried out in the processing chamber 72, and a TiN film is formed on the surface of the substrate.

Next, the substrate inside the processing chamber 72 is unloaded by the transfer robot arm 13a of the transfer chamber 13 and transferred to the substrate mount inside the handoff vacuum chamber 32 (pathway R507). The transfer robot arm 12a of the transfer chamber 12 then loads the substrate into the processing chamber 61 (pathway R508).

An RTP (Rapid Thermal Process) process is carried out in the processing chamber 61.

Lastly, the substrate inside the processing chamber 61 is loaded by the transfer robot arm 12a of the transfer chamber 12 into the load-lock chamber 82 (pathway R509).

In the substrate process of operational example 4 described above, the heating process in the handoff vacuum chamber 31 is also carried out in the common vacuum chamber 21, and the preheating process can also be carried out in the common vacuum chamber 21. Processing times are thereby synchronized with other processing times, the substrate wait time can be reduced, and throughput can be improved.

### Operational Example 5

Operational example 5 is a substrate process related to “source/drain salicide processing.” FIG. 9 shows a specific substrate movement pathway (R601 to R610, R616, and R617) that corresponds to the substrate process of operational example 5, and is the same diagram as FIG. 4. In FIG. 9, the same reference numerals are used for the same chambers as those described in FIG. 2. The transfer robot arms 11a to 13a disposed inside the transfer chambers 11 to 13 are omitted from the diagram.

In the process shown in FIG. 9, the substrate is first set inside the load-lock chamber 81 (pathway R601). The substrate inside the load-lock chamber 81 is moved by the transfer robot arm 11a of the transfer chamber 11 through the interior of the transfer chamber 11 and loaded into the processing chamber 51 (pathway R602). A chemical process is carried out in the processing chamber 51.

Next, the substrate inside the processing chamber 51 is moved by the transfer robot arm 11a of the transfer chamber 11 through the interior of the transfer chamber 11 into the processing chamber 52 (pathway R603). A heating or plasma process is carried out in the processing chamber 52.

The substrate inside the processing chamber 52 is transferred by the transfer robot arm 11a of the transfer chamber 11 through the transfer chamber 11 to the substrate mount of the handoff vacuum chamber 31 (pathway R604). The substrate on the substrate mount is thereafter transferred by the transfer robot arm 13a, of the transfer chamber 13 into the transfer chamber 13 and loaded into the processing chamber 71 (pathway R605). At this point, the substrate is preheated in the handoff vacuum chamber 31. The processing time in the processing chamber 71 can thereby be reduced. An SiEpi film is deposited [on the substrate] in the processing chamber 71.

Next, the substrate inside the processing chamber 71 is loaded by the transfer robot arm 13a of the transfer chamber 13 and is transferred to the substrate mount inside the handoff vacuum chamber 32 (pathway R606). The substrate is thereafter transferred by the transfer robot arm 12a of the transfer chamber 12 into the processing chamber 61 (pathway R607). PVD is carried out in the processing chamber 61, and a film composed of Co, Ni, Ti, or Y, Yb, Er, or another rare earth metal is formed on the surface of the substrate. A preheating process is carried out in the handoff vacuum chamber 32. As a result, the processing time in the processing chamber 61 can be reduced.

In the description above, pathways R616 and R617 may be created in the case of pathway R606, and alignment can be carried out using the common vacuum chamber 21.

Next, the substrate inside the processing chamber 61 is unloaded by the transfer robot arm 12a of the transfer chamber 12 and is loaded into the neighboring processing chamber 62 (pathway R608). A process for forming a film as a cap layer is carried out in the processing chamber 62 by PVD.

Next, the substrate inside the processing chamber 62 is unloaded by the transfer robot arm 12a of the transfer chamber 12 and placed on the substrate mount of the common vacuum chamber 21 (pathway R609). A heat process is carried out in the common vacuum chamber 21.

Lastly, the substrate inside the processing chamber 21 is loaded by the transfer robot arm 12a of the transfer chamber 12 into the load-lock chamber 82 (pathway R610).

In the substrate process of operational example 5 described above, a post-annealing process is carried out in the common vacuum chamber 21. The substrate can thereby be uniformly heated by gas heating. The common vacuum chamber 21 and handoff vacuum chambers 31 and 32 can be used not only as a substrate transfer pathway, but also for substrate heating, cooling, and alignment.

Next, the method using the vacuum processing apparatus 10 in correspondence with the method of setting the substrate transfer pathway in the vacuum processing apparatus 10 described above will be described with reference to FIGS. 10A and 10B.

FIGS. 10A and 10B show the same diagram as FIG. 4 and show the substrate transfer pathway. In FIGS. 10A and 10B, the same reference numerals are used for the same chambers as those described in FIG. 2, and a description thereof is omitted. The transfer robot arms 11a to 13a disposed inside the transfer chambers 11 to 13 are omitted from the diagram. In FIGS. 10A and 10B, the substrate movement pathway that corresponds to the processing chamber is omitted from the diagram.

In FIG. 10A, two symmetrical transfer pathways, i.e., pathway R651 indicated by a solid line and pathway 652 indicated by a broken line, are shown as the substrate transfer pathways. The pathway R651 is a transfer pathway in which a substrate enters from the load-lock chamber 81, moves in sequence through the transfer chamber 11, transfer chamber 13, and transfer chamber 11, and exits from the load-lock chamber 81. Here, the handoff vacuum chamber 31 and the common vacuum chamber 21 are used for transferring substrates. On the other hand, the pathway R652 is a transfer pathway in which a substrate enters from the load-lock chamber 82, moves in sequence through the transfer chamber 12, transfer chamber 13, and transfer chamber 12, and again passes through and exits from the load-lock chamber 82. Here, the handoff vacuum chamber 32 and the common vacuum chamber 21 are used for transferring substrates. In the description above, the transfer chamber 13 is used as a shared transfer chamber by the left and right pathways R651 and R652. The left and right transfer chambers 11 and 12 are used as transfer chambers for different substrate processes.

The substrate transfer pathway is set in the manner indicated by the pathways R651 and R652 shown in FIG. 10A, whereby shared left and right substrate movement pathways can be used at the same time for two different left and right substrate processes. Therefore, two left and right steps can be used simultaneously for separate processes, and the vacuum processing apparatus 10 can be used in an efficient manner.

In FIG. 10B, two symmetrical transfer pathways, i.e., pathway R661 indicated by a solid line and pathway R662 indicated by a broken line, are shown as the substrate transfer pathways. The pathway R661 is a transfer pathway in which a substrate enters from the load-lock chamber 81, moves in sequence through the transfer chamber 11, transfer chamber 13, and transfer chamber 12, and exits from the load-lock chamber 82. Here, the handoff vacuum chamber 31 and the common vacuum chamber 21 are used for transferring substrates. On the other hand, the pathway R662 is a transfer pathway in which a substrate enters from the load-lock chamber 82, moves in sequence through the transfer chamber 12, transfer chamber 13, and transfer chamber 11, and exits from the load-lock chamber 81. Here, the handoff vacuum chamber 32 and the common vacuum chamber 21 are used for transferring substrates. In the description above, the transfer chamber 13 is used as a shared transfer chamber by the left and right pathways R661 and R662. The left and right transfer chambers 11 and 12 are used as transfer chambers for different substrate processes.

The substrate transfer pathway is set in the manner indicated by the pathways R661 and R662 shown in FIG. 10B. In this case as well, the shared left and right substrate movement pathways can be used at the same time for two different left and right substrate processes. Therefore, two left and right steps can be used simultaneously for separate processes, and the vacuum processing apparatus 10 can be used in an efficiently manner.

### Embodiment 3

Next, the third embodiment of the vacuum processing apparatus of the present invention will be described with reference to FIG. 11. FIG. 11 shows a simplified diagrammatic view of a vacuum processing apparatus 101 according to the third embodiment. The same reference numerals are used for essentially the same elements as those described in FIG. 2.

The vacuum processing apparatus is provided with three transfer chambers 11, 12, and 13. The transfer chambers are provided with processing chambers 51, 52; 61, 62; and 71 to 75, respectively. The transfer chambers 11 and 12 are provided with load-lock chambers 81 and 82, respectively. The transfer robot arms 11a, 12a, and 13a are disposed inside the three transfer chambers 11, 12, and 13, respectively, but are not depicted in the diagram.

A common vacuum chamber 102 is disposed in an intermediate position of the three transfer chambers 11 to 13. The function of the common vacuum chamber 120 is the same as the function of the common vacuum chamber 21 described above. The feature of the configuration of the common vacuum chamber 102 is that the chamber is provided with two substrate mounts 102a and 102b in the interior thereof. The transfer robot arms 11a to 13a of the transfer chambers 11 to 13 are in positions that allow the arms to reach the two substrate mounts 102a and 102b of the common vacuum chamber 102. The substrate can be freely moved by the transfer robot arms 11a to 13a of the transfer chambers 11 to 13 in a mutual fashion among the two substrate mounts 102a and 102b of the common vacuum chamber 102 and the substrate mounts of other processing chambers, the handoff vacuum chamber, and the like.

In FIG. 11, the handoff vacuum chamber disposed on the two sides of the common vacuum chamber 102 is omitted from the diagram for the sake of convenience.

### Embodiment 4

Next, the fourth embodiment of the vacuum processing apparatus according to the present invention is described with reference to the FIG. 12. In FIG. 12, the same reference numerals are used for essentially the same elements as those described in FIG. 1. The vacuum processing apparatus 301 of this embodiment has a chamber layout configuration that is provided with four transfer chambers 11, 12, 13, and 302. In the configuration of the vacuum processing apparatus 301 shown in FIG. 12, only the connection structure of the transfer chambers is schematically shown as a plan view. Therefore, the transfer robot arms, the substrate mounts, the gate valves, and the like are omitted from the diagram.

In FIG. 12, the transfer chambers 11, 12, and 13 and the common vacuum chamber 21 are essentially the same as those described with reference to the vacuum processing apparatus 10 according to the first embodiment. The configuration and operation related to handing off the substrate of the transfer chambers 11 to 13 to the common vacuum chamber 21 are the same as those described in the first embodiment.

The added transfer chamber 302 has an transfer robot arm (not shown) disposed inside the chamber in the same manner as in the transfer chambers 11 to 13, and has essentially the same configuration as the transfer chambers 11 to 13. Therefore, a substrate as the processing object can also be handed off from the transfer chamber 302 to the common vacuum chamber 21. In the vacuum processing apparatus 301 having the four transfer chambers 11, 12, 13, and 302, the load-lock chambers 81 and 82 are provided to the first transfer chamber 11 and the fourth transfer chamber 302, respectively.

In the vacuum processing apparatus 301, two vacuum chambers 303 and 304 are disposed between the transfer chambers 11 and 12, and between the transfer chambers 13 and 302, respectively, as vacuum chambers other than the above-described common vacuum chamber 21 for the purpose of increasing productivity. The number and set positions of vacuum chambers other than the common vacuum chamber 21 can be arbitrarily selected.

Other configurations in the vacuum processing apparatus 301 are essentially the same as the configuration of the embodiments described above. The four transfer chambers 11, 12, 13, and 302 are each provided with one or more processing chambers. However, only the processing chambers 51, 61, 71, and 305, one for each of the transfer chambers 11, 12, 13, and 302, are shown in FIG. 12 for the sake convenience.

Described below is a preferred example of the substrate process carried out in the vacuum processing apparatus 301 having the four transfer chambers 11, 12, 13, and 302 described above, the common vacuum chamber 21, and the vacuum chambers 303 and 304. In FIG. 12, the substrate transfer pathways R701 to R704, R711, and R712 are shown.

An epitaxial doping process is carried out in the area of the source and drain using the vacuum processing apparatus 301. In the doping process, boron (B) and phosphorus (P) are doped in large quantities, i.e., 10²⁰ cm⁻³ or more. Therefore, about 10⁺⁷ cm⁻³ of the boron or phosphorus that remains in the transfer chamber still remains even if the pressure reaches 10⁻⁷ Pa when the interior of the transfer chamber is evacuated. Therefore, separate transfer chambers must be used in accordance with the boron process and the phosphorus process.

In view of the above, with boron doping, (1) the transfer robot arm of the transfer chamber 11 transfers the substrate via the pathway R701 to the processing chamber 51, where a pre process is carried out; (2) the transfer robot arms of the transfer chambers 11 and 12 and the handoff vacuum chamber 303 subsequently transfer the substrate via the pathway R702 to the processing chamber 61, where the boron doping process is carried out; (3) the transfer robot arms of the transfer chambers 12 and 302 and the common vacuum chamber 21 then transfer the substrate via the pathway R703 to the processing chamber 305, where an RTP (Rapid Thermal Process) is carried out; and (4) the transfer robot arm of the transfer chamber 302 then loads the substrate via the pathway R704 into the load-lock chamber 82, whereby a process system is formed.

With phosphorus doping, (1) the transfer robot arm of the transfer chamber 11 transfers the substrate to the processing chamber 51 via the pathway R701, and a pre process is carried out; (2) the transfer robot arms of the transfer chambers 11 and 13 and the common vacuum chamber 21 subsequently transfer the substrate via the pathway R711 to the processing chamber 71, where the phosphorus doping process is carried out; (3) the transfer robot arms of the transfer chambers 13 and 302 and the handoff vacuum chamber 304 then transfer the substrate via the pathway R712 to the processing chamber 305, where an RTP (Rapid Thermal Process) is carried out; and (4) the transfer robot arm of the transfer chamber 302 then loads the substrate via the pathway R704 into the load-lock chamber 82, whereby a process system is formed.

In accordance with the vacuum processing apparatus 301 of the fourth embodiment, any three of the transfer chambers are suitably selected from the four transfer chambers 11, 12, 13, and 302, whereby an assembly of different transfer chambers can be formed, and the mutual effect of the processes can be eliminated by using different pathways as the transfer pathways of the processes.

In accordance with the vacuum processing apparatus 301 of the fourth embodiment described above, any three of the transfer chambers are suitably selected from the four transfer chambers 11, 12, 13, and 302, whereby the apparatus can be used as the vacuum processing apparatus 10 of the second embodiment described above.

### Embodiment 5

Next, an embodiment of the method for manufacturing a semiconductor device and a system for manufacturing a semiconductor that use the vacuum processing apparatus 10, for example, will be described with reference to FIGS. 13 to 15.

FIG. 13 shows the overall configuration of the system for manufacturing a semiconductor device that uses the vacuum processing apparatus of the present invention. FIG. 14 shows the flow of the overall manufacturing process of a semiconductor device. FIG. 15 shows the flow of the wafer process performed by the system for manufacturing a semiconductor device shown in FIG. 13.

The system for manufacturing a semiconductor device shown in FIG. 13 is depicted as an overall inline manufacturing system. The reference numeral 401 is a substrate transfer pathway whereby a substrate treated in each step is transferred to the next step. An apparatus that corresponds to each step is disposed along the substrate transfer pathway 401. In accordance with the system configuration shown in FIG. 13, the vacuum processing apparatus 10 according to the present invention is disposed, as an example, in the first step. A resist coater 402 as a second step, a stepper 403 as an exposure apparatus in the third step, a resist developer 404 as a fourth step, and an etcher 405 as a fifth step are thereafter disposed along the substrate transfer pathway 401.

Next, in FIG. 14, the circuit of a semiconductor device is designed in step S1 (circuit design). In step S2 (mask fabrication), a mask that forms the designed circuit pattern is fabricated. Meanwhile, wafer is manufactured using silicon or the like in step S3 (wafer manufacture). Step S4 (wafer process) is referred to as a pre-step, and the actual circuit is lithographically formed on the wafer using the mask and wafer prepared above. The next step S5 (assembly) is referred to as a post-step, is a step for forming a semiconductor chip using the wafer fabricated in step S4, and includes an assembly step (dicing, bonding), a packaging step (chip sealing), and other assembly steps. In step S6 (inspection), a test for confirming the operation of the semiconductor device fabricated in step S5, a durability test, and other inspections are carried out. The semiconductor device is completed via such steps and then shipped (step S7).

In the overall manufacturing process of the semiconductor device described with reference to FIG. 14, the system for manufacturing a semiconductor device shown in FIG. 13 is used in the wafer process (step S4). Next, an example of the wafer process carried out in the system for manufacturing a semiconductor device will be described with reference to FIG. 15.

In FIG. 15, the surface of the wafer is oxidized in step S11 (oxidation step). An insulation film is formed on the surface of the wafer in step S12 (CVD step). In step S13 (electrode formation step), an electroconductive film as an electrode is formed on the wafer by PVD, CVD, or other vapor deposition. Steps S11 to S13 can be carried out in the vacuum processing apparatus 10 described above. The processing steps in the at least three transfer chambers of the vacuum processing apparatus of the present invention are not limited to an oxidation step, CVD step, and electrode formation step. In addition to these steps, it is also possible to carry out processes suitably selected from substrate cleaning, nitriding, PVD, plasma processing, and various other processes.

A step for implanting ions in a wafer may also be separately provided in the manner shown in step S14 (ion implantation step).

Next, a photosensitizer is applied to the wafer in step S15 (resist processing step). Step S15 is carried out in the resist coater 402. In step S16 (exposure step), the circuit pattern of the mask is exposed and printed onto the wafer using the exposure apparatus described above. Step S16 is carried out in the stepper 403. The exposed wafer is developed in step S17 (development step). Step S17 is carried out in the resist developer 404. The portions other than the developed resist image are removed in step S18 (etching step). Step S18 is carried out in the etcher 405. The etching is completed and the unnecessary resist is removed in step S19 (resist removal step). In this example, step S19 is carried out in a resist removal apparatus (not shown).

A processing chamber having a function for carrying out the etching step of step S18 and the resist removal step of step S19 may also be provided to the vacuum processing apparatus 10 as described above.

Multiple layers of circuit patterns are formed on the wafer by repeating the step described above. The manufacturing equipment used in the steps is maintained by, e.g., a remote maintenance system.

### INDUSTRIAL APPLICABILITY

The present invention can be used in the process of a substrate using a vacuum processing apparatus in order to improve the degree of freedom of selecting the transfer pathway of the substrate as a processing object, to improve the degree of freedom of combining substrate processes, and to increase the efficiency and productivity of substrate process.

### BRIEF DESCRIPTION OF THE DRAWINGS

FIG. 1 is a plan view that schematically shows a first embodiment, which is the basic configuration of the vacuum processing apparatus of the present invention;

FIG. 2 is a plan view that schematically shows a second embodiment of the vacuum processing apparatus of the present invention;

FIG. 3 is a plan view showing an example of the transport pathway of a substrate in the vacuum processing apparatus of the second embodiment;

FIG. 4 is a diagram of the substrate movement pathway that describes a typical operational example of a substrate process that is carried out using the vacuum processing apparatus of the second embodiment;

FIG. 5 is a diagram of the substrate movement pathway that describes operational example 1 of a substrate process that is carried out using the vacuum processing apparatus of the second embodiment;

FIG. 6 is a diagram of the substrate movement pathway that describes operational example 2 of a substrate process that is carried out using the vacuum processing apparatus of the second embodiment;

FIG. 7 is a diagram of the substrate movement pathway that describes operational example 3 of a substrate process that is carried out using the vacuum processing apparatus of the second embodiment;

FIG. 8 is a diagram of the substrate movement pathway that describes operational example 4 of a substrate process that is carried out using the vacuum processing apparatus of the second embodiment;

FIG. 9 is a diagram of the substrate movement pathway that describes operational example 5 of a substrate process that is carried out using the vacuum processing apparatus of the second embodiment;

FIG. 10A is a diagram of the substrate transfer pathway that describes a first example of the method of setting the substrate transfer pathway of the vacuum processing apparatus of the second embodiment;

FIG. 10B is a diagram of the substrate transfer pathway that describes a second example of the method of setting the substrate transfer pathway of the vacuum processing apparatus of the second embodiment;

FIG. 11 is a plan view that schematically shows a third embodiment of the vacuum processing apparatus of the present invention;

FIG. 12 is a plan view that schematically shows a fourth embodiment of the vacuum processing apparatus of the present invention;

FIG. 13 is a view of the overall configuration showing an embodiment of the system for manufacturing a semiconductor device that uses the vacuum processing apparatus of the present invention;

FIG. 14 is a flowchart showing the flow of the overall manufacturing process of a semiconductor device that is performed by the system for manufacturing a semiconductor device of the present embodiment; and

FIG. 15 is a flowchart showing in detail an example of the flow of the wafer process performed by the system for manufacturing a semiconductor device shown in FIG. 13.

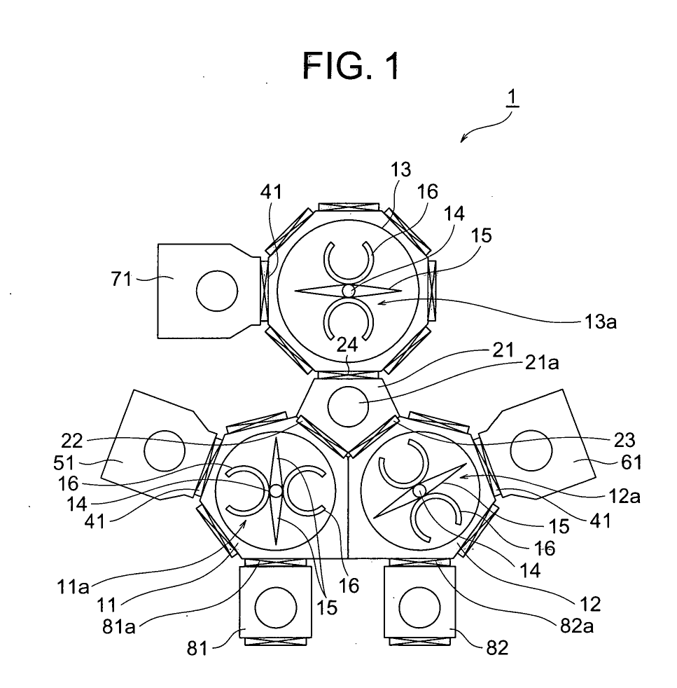

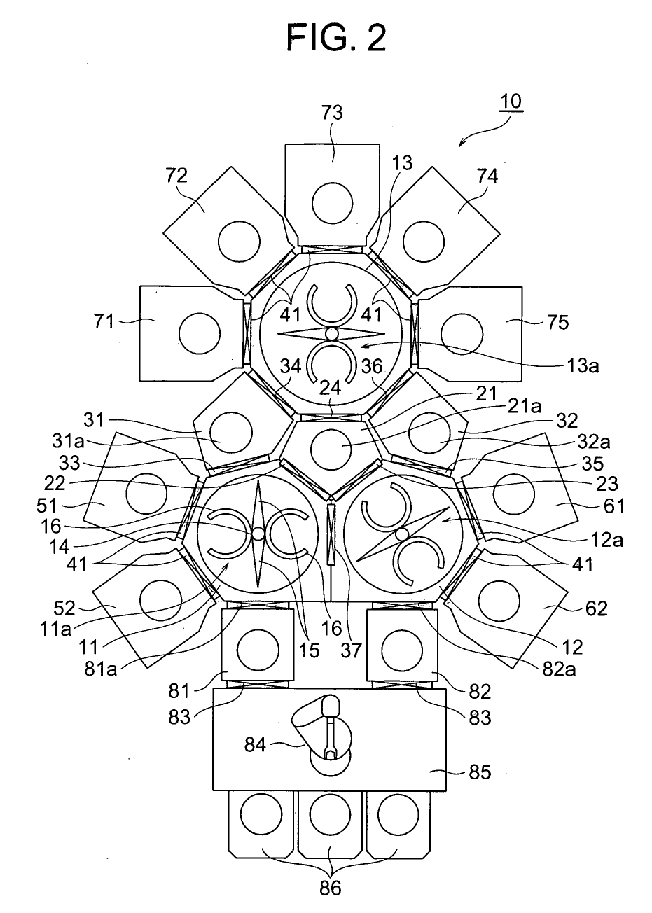

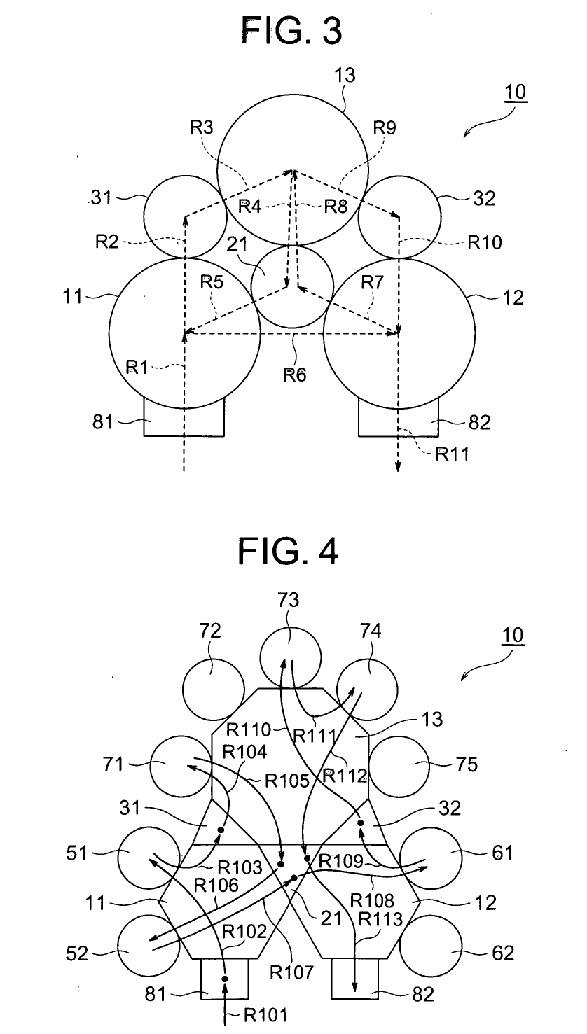

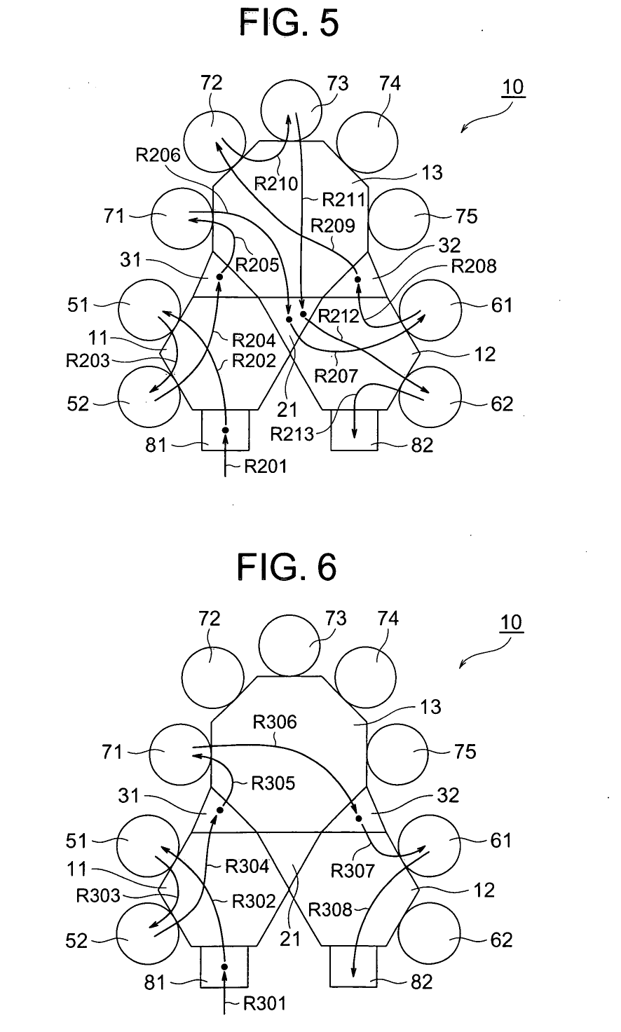

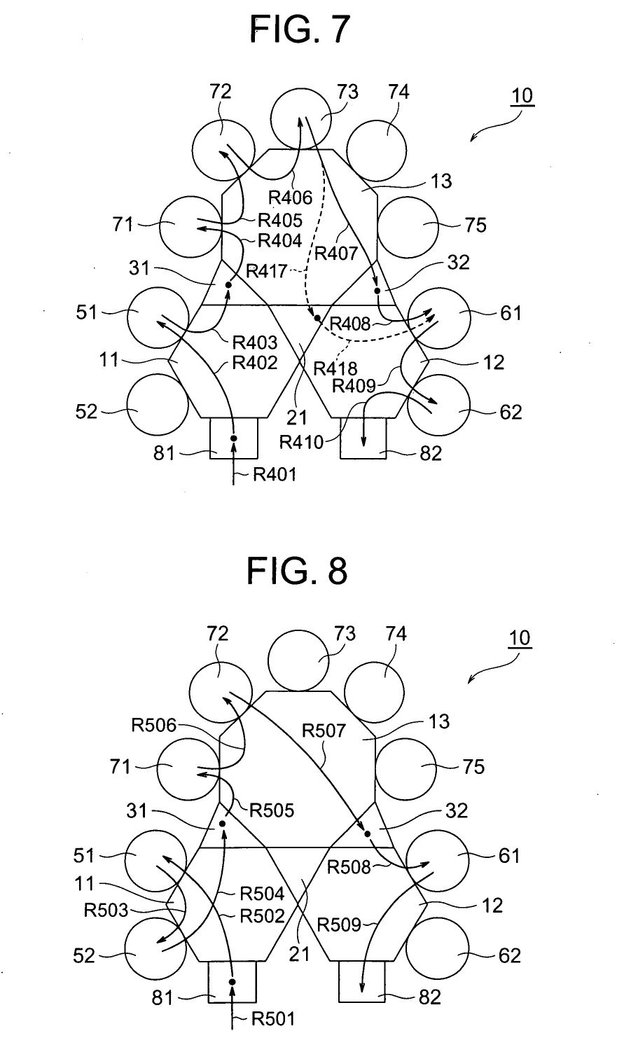

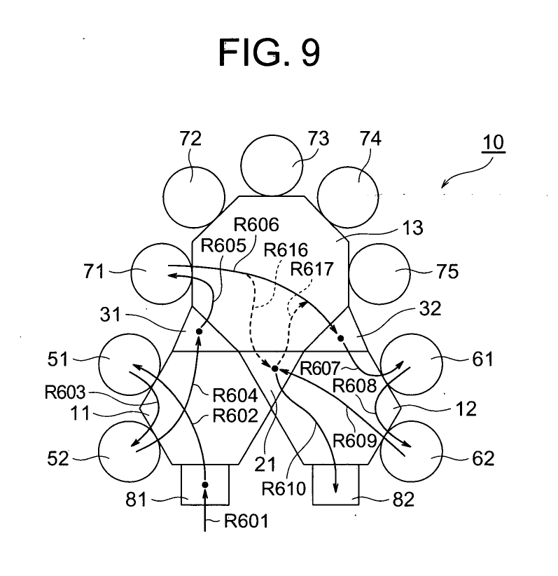

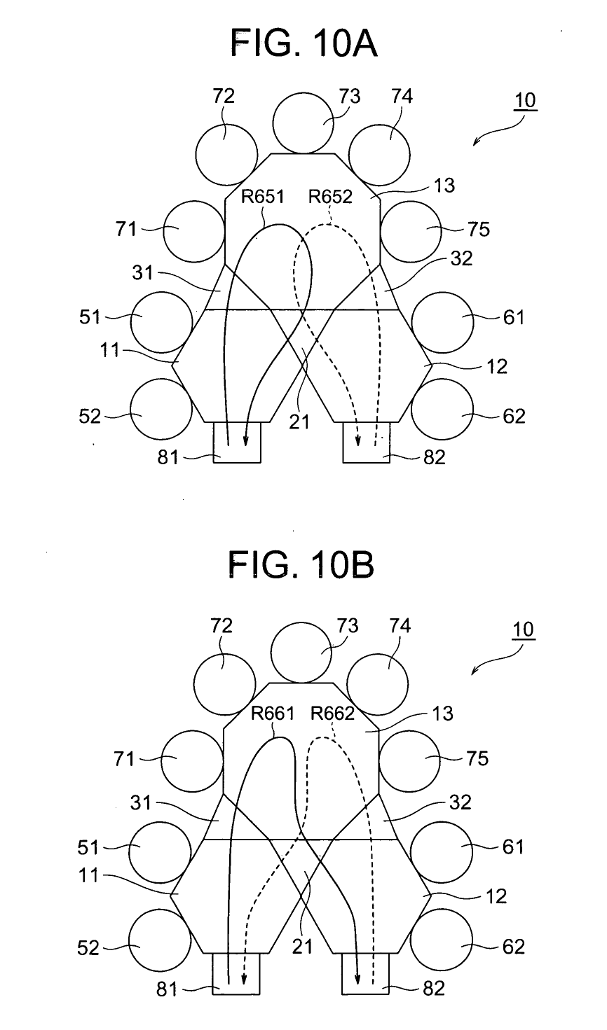

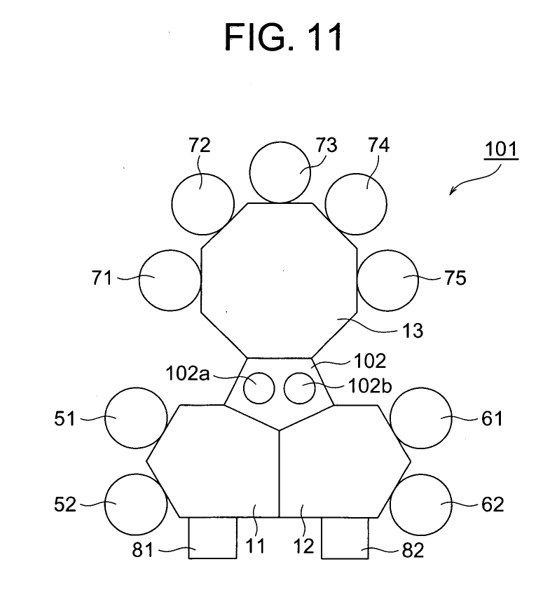

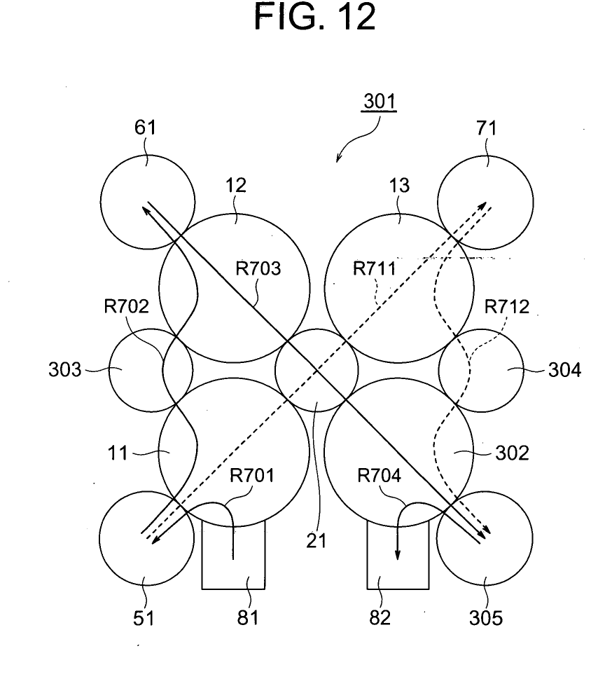

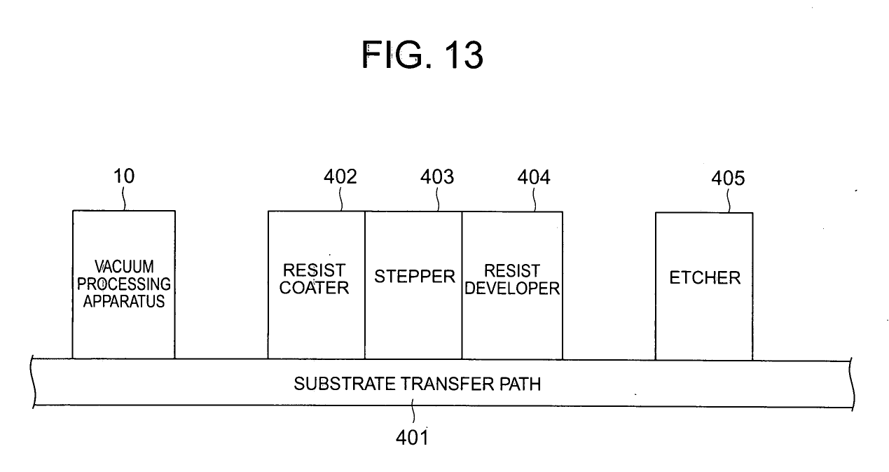

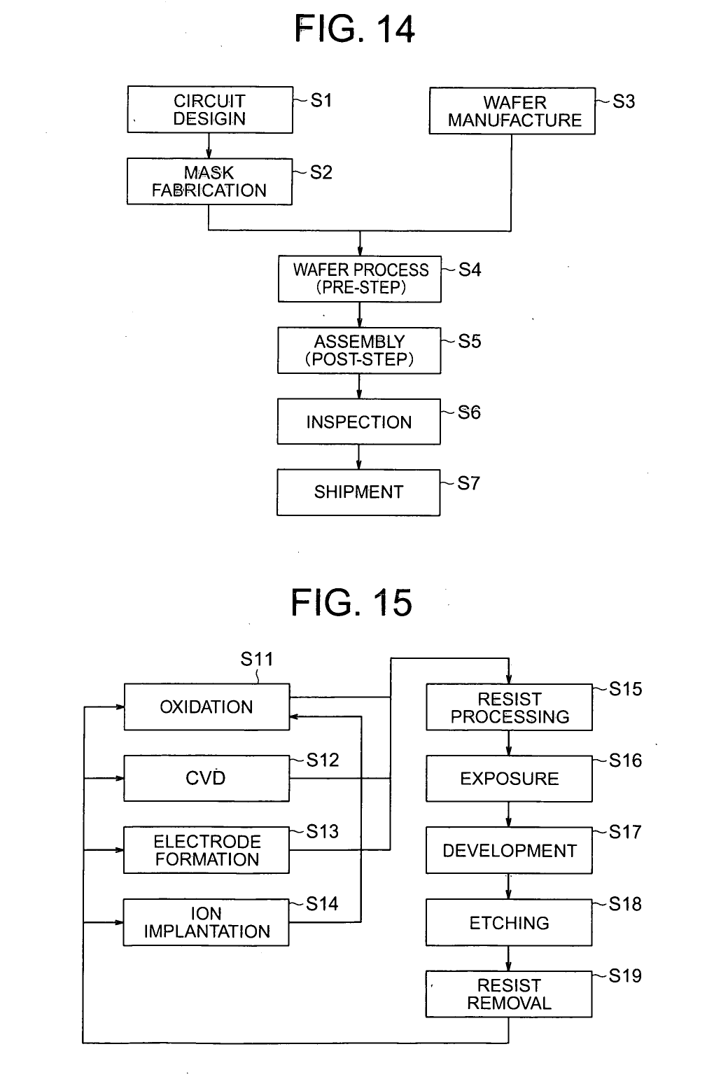

### EXPLANATION OF REFERENCE NUMBERS

1 Vacuum processing apparatus
10 Vacuum processing apparatus
11, 12, 13 Transfer chambers
11a, 12a, 13a Transfer robot arms
21 Common vacuum chamber
31, 32 Handoff vacuum chambers
51, 52, 53 Processing chambers
61, 62, Processing chambers
71 to 75 Processing chambers
101 Vacuum processing apparatus
301 Vacuum processing apparatus

1-20. (canceled)

21. A vacuum treatment apparatus, comprising:
at least three transfer chambers each of which is provided in the interior thereof with a transfer robot arm for transferring a substrate;
treatment chambers at least one of which is connected to each of said transfer chambers, and inside which the substrate is treated;
a single common vacuum chamber inside which one or more substrate mounts are disposed, in which the transfer robot arm of each of the at least three transfer chambers is disposed so as to be capable of reaching the substrate mounts, and which is used by the transfer robot arm to hand off the substrate among at least two of the transfer chambers and at least one of the substrate mounts; and
load-lock chambers connected to at least one of said transfer chambers;
wherein the plurality of treatment chambers connected to the same transfer chamber are treatment chambers that belong to the same category and are classified by the treatment pressure and the content and extent of contamination brought about by the treatment.

22. The vacuum treatment apparatus of claim 21, wherein said transfer robot arms of the transfer chambers are capable of moving the substrate to the substrate mounts inside the common vacuum chamber.

23. The vacuum treatment apparatus of claim 21, wherein four or more of the transfer chambers are provided.

24. The vacuum treatment apparatus of claim 21, wherein a single handoff vacuum chamber is disposed between at least one set of two adjacent transfer chambers among the at least three transfer chambers.

25. The vacuum treatment apparatus of claim 21, wherein the load-lock chambers are separately provided to each of the two transfer chambers.

26. The vacuum treatment apparatus of claim 21, wherein the common vacuum chamber is provided with the substrate mounts and an alignment sensor, and the substrate mounts are rotatable.

27. The vacuum treatment apparatus of claim 21, wherein the common vacuum chamber is provided with one or both of a heater stage for heating and a cooling stage for cooling.

28. The vacuum treatment apparatus of claim 21, wherein the common vacuum chamber is provided with a monitor apparatus for monitoring a surface state of the substrate.

29. The vacuum treatment apparatus of claim 21, wherein the common vacuum chamber is provided with a cassette that is capable of accommodating a plurality of substrates, a mechanism for elevating/lowering the cassette, and a rotation mechanism for rotating the cassette.

30. The vacuum treatment apparatus of claim 21, wherein the transfer chambers, the common vacuum chamber, and the handoff vacuum chamber are partitioned by a gate valve.

31. The vacuum treatment apparatus of claim 21, wherein the common vacuum chamber is a chamber for performing at least one operation selected from aligning the substrate, heating the substrate, cooling the substrate, monitoring a surface state of the substrate, and stocking the substrate.

32. A method for manufacturing a semiconductor device, the method for manufacturing a semiconductor device comprising:
providing a vacuum treatment apparatus described in claim 21; and
subjecting a substrate to at least three treatments using the vacuum treatment apparatus.

33. A method for manufacturing a semiconductor device that includes a wafer process, the method for manufacturing a semiconductor device comprising the wafer process comprising:
an oxidation step that is carried out in a first treatment chamber among the at least three treatment chambers that are provided in the vacuum treatment apparatus of claim 21;
a CVD step that is carried out in a second treatment chamber provided in the vacuum treatment apparatus; and
an electrode formation step that is carried out in a third treatment chamber provided in the vacuum treatment apparatus.

34. The method for manufacturing a semiconductor device of claim 33, wherein the wafer process includes a resist treatment step, an exposure step, a development step, and an etching step that are carried out in an apparatus other than the vacuum treatment apparatus after the oxidation step, the CVD step, and the electrode formation step have been carried out in the vacuum treatment apparatus.

35. A system for manufacturing a semiconductor device comprising the vacuum treatment apparatus of claim 21, a resist coater, a stepper, a resist developer, and an etcher to carry out a wafer process, the system for manufacturing a semiconductor device comprising:
the wafer process including at least three substrate treatment steps; and
at least three substrate treatment steps being carried out in the vacuum treatment apparatus.

36. A system for manufacturing a semiconductor device comprising the vacuum treatment apparatus of claim 21, a resist coater, a stepper, a resist developer, and an etcher to carry out a wafer process, the system for manufacturing a semiconductor device comprising:
the wafer process including said oxidation step, a CVD step, and an electrode formation step; and
the vacuum treatment apparatus having a first treatment chamber for carrying out the oxidation step, a second treatment chamber for carrying out the CVD step, and a third treatment chamber for carrying out the electrode formation step.

37. The system for manufacturing a semiconductor device of claim 36, wherein the oxidation step, the CVD step, and the electrode formation step being carried out in the vacuum treatment apparatus, whereupon
the resist coater performs a resist treatment step,
the stepper performs an exposure step,
the resist developer performs a development step, and
the etcher performs an etching step.

38. The vacuum treatment apparatus of claim 24, wherein the handoff vacuum chamber is a chamber in which at least one substrate treatment selected from heating the substrate, cooling the substrate, and aligning the substrate is carried out.

39. The vacuum treatment apparatus of claim 38, wherein the common vacuum chamber is merely used as a substrate transfer path.
